(19) United States
(12) Patent Application Publication
(10) Pub. No.: US 2025/0159934 A1
(43) Pub. Date: May 15, 2025

(54) TRANSISTOR STRUCTURES, DRIVING SUBSTRATES AND DISPLAY PANELS

(71) Applicant: WUHAN CHINA STAR OPTOELECTRONICS TECHNOLOGY CO., LTD., Wuhan, Hubei (CN)

(72) Inventors: SUNG MIN HAN, Wuhan, Hubei (CN); Jianqin LIN, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/575,287

(22) PCT Filed: Nov. 20, 2023
(86) PCT No.: PCT/CN2023/132517

§ 371 Date: Dec. 28, 2023

(30) Foreign Application Priority Data
Nov. 14, 2023 (CN) 202311530507.3

(51) Int. Cl. H01L 29/786

(52) U.S. Cl. CPC H10D 30/6745

(57) ABSTRACT

Disclosed are a transistor structure, a driving substrate and a display panel. The transistor structure includes a substrate, a buffer layer and a transistor, and the buffer layer is disposed on the substrate. The transistor is disposed on a side of the buffer layer away from the substrate. The buffer layer includes a first silicon oxide layer and a second silicon oxide layer stacked on the substrate in sequence. A hydrogen content of the second silicon oxide layer is greater than 4%, and a hydrogen content of the first silicon oxide layer is less than the hydrogen content of the second silicon oxide layer.

### TECHNICAL FIELD

The present disclosure relates to display technologies, and in particular, to transistor structures, driving substrates and display panels.

### BACKGROUND

In the film layer design of a conventional low temperature poly-silicon display device having a top gate structure, a buffer layer generally adopts a stacked structure of silicon nitride+silicon oxide. However, since a light transmittance of silicon nitride is less than that of silicon oxide, that is, there is a difference in refractive index, it results in quality problems such as blind hole bluing and integrated black. At the same time, silicon nitride is not easily etched and thus remains, causing yellowing at the corners.

Therefore, in the related art, a fully silicon oxide buffer layer is used to replace the stacked structure of silicon nitride+silicon oxide to solve the above technical problems. However, due to power instability of the deposition equipment in early stages of buffer layer formation, it can result in a poor quality of the underlying film, which in turn affects the stability of film quality of the entire buffer layer.

### SUMMARY

Embodiments of the present disclosure provide a transistor structure, a driving substrate and a display panel, which can improve the stability of film quality of the buffer layer.

An embodiment of the present disclosure provides a transistor structure including:
a substrate;
a buffer layer disposed on the substrate; and
a transistor disposed on a side of the buffer layer away from the substrate;
the buffer layer includes a first silicon oxide layer and a second silicon oxide layer stacked on the substrate in sequence, a hydrogen content of the second silicon oxide layer is greater than 4%, and a hydrogen content of the first silicon oxide layer is less than the hydrogen content of the second silicon oxide layer.

Accordingly, an embodiment of the present disclosure further provides a driving substrate, and the driving substrate includes the transistor structure described in the above embodiment.

Accordingly, an embodiment of the present disclosure further provides a display panel, and the display panel includes the driving substrate described in the above embodiment.

### BRIEF DESCRIPTION OF THE DRAWINGS

FIG. 1 is a schematic structural diagram of a transistor structure provided by an embodiment of the present disclosure;

FIG. 2 is a comparison chart of the stability of electron mobility of N-type thin film transistors (TFT);

FIG. 3 is a comparison chart of the stability of electron mobility of P-type thin film transistors (TFT);

FIG. 4 is a curve of SiO content of a sample-buffer layer analyzed using TOF SIMS.

### DETAILED DESCRIPTION

Technical solutions in embodiments of the present disclosure will be clearly and completely described below with reference to the accompanying drawings in embodiments of the present disclosure. Apparently, embodiments described herein are only some of the embodiments of the present disclosure, rather than all of the embodiments of the present disclosure. Based on the embodiments of the present disclosure, all other embodiments obtained by those skilled in the art without making creative efforts fall within the protection scope of the present disclosure. In addition, it should be understood that specific embodiments described herein are only intended to illustrate and explain the present disclosure, and are not intended to limit the present disclosure. In this disclosure, unless otherwise specified, directional terms used herein, such as “upper” and “lower”, generally refer to upper and lower positions of a device in actual use or working conditions, specifically refer to directions in the surfaces of the accompanying drawings. Terms “inside” and “outside” are for the contour of the device; and terms “first”, “second”, “third”, and the like, are used merely as designators and do not impose numerical requirements or establish a sequence.

Embodiments of the present disclosure provide a transistor structure, a driving substrate and a display panel, which will be described in detail below. It should be noted that the order of description of the following embodiments does not limit the preferred order of the embodiments.

An embodiment of the present disclosure provides a transistor structure including:
a substrate;
a buffer layer disposed on the substrate; and
a transistor disposed on a side of the buffer layer away from the substrate;
the buffer layer includes a first silicon oxide layer and a second silicon oxide layer stacked on the substrate in sequence, a hydrogen content of the second silicon oxide layer is greater than 4%, and a hydrogen content of the first silicon oxide layer is less than the hydrogen content of the second silicon oxide layer.

Optionally, in some embodiments of the present disclosure, the hydrogen content of the first silicon oxide layer is less than or equal to 4%.

Optionally, in some embodiments of the present disclosure, a thickness of the first silicon oxide layer is greater than or equal to 500 angstroms.

Optionally, in some embodiments of the present disclosure, a refractive index of the second silicon oxide layer is greater than a refractive index of the first silicon oxide layer.

Optionally, in some embodiments of the present disclosure, a thickness of the second silicon oxide layer is greater than a thickness of the first silicon oxide layer.

Optionally, in some embodiments of the present disclosure, the hydrogen content of the second silicon oxide layer is between 5% and 9%.

Optionally, in some embodiments of the present disclosure, the refractive index of the second silicon oxide layer is between 1.50 and 1.58.

Optionally, in some embodiments of the present disclosure, the buffer layer further includes a third silicon oxide layer stacked on a side of the second silicon oxide layer away from the substrate, and a hydrogen content of the third silicon oxide layer is less than the hydrogen content of the second silicon oxide layer.

Optionally, in some embodiments of the present disclosure, the hydrogen content of the third silicon oxide layer is greater than or equal to 2% and less than or equal to 4%.

Optionally, in some embodiments of the present disclosure, a thickness of the first silicon oxide layer is between 500 angstroms and 1000 angstroms, a thickness of the second silicon oxide layer is between 1000 angstroms and 2000 angstroms, a thickness of the third silicon oxide layer is between 500 angstroms and 1000 angstroms, and a refractive index of the second silicon oxide layer is greater than a refractive index of the third silicon oxide layer.

Optionally, in some embodiments of the present disclosure, a refractive index of the first silicon oxide layer is between 1.45 and 1.49, and the refractive index of the third silicon oxide layer is between 1.45 and 1.49.

Optionally, in some embodiments of the present disclosure, the hydrogen content of the first silicon oxide layer is greater than or equal to 2%.

Optionally, in some embodiments of the present disclosure, the transistor includes an active layer, a gate insulating layer, a gate, a source and a drain, and the active layer is disposed on the side of the buffer layer away from the substrate, the gate insulating layer covers the active layer, the gate is disposed on a side of the gate insulating layer away from the substrate, the source is connected to one end of the active layer, the drain is connected to another end of the active layer, and a material of the active layer is monocrystalline silicon or polycrystalline silicon.

Accordingly, an embodiment of the present disclosure further provides a driving substrate, and the driving substrate includes the transistor structure described in any of the above embodiments. For example, the transistor structure includes:
a substrate;
a buffer layer disposed on the substrate; and
a transistor disposed on a side of the buffer layer away from the substrate;
the buffer layer includes a first silicon oxide layer and a second silicon oxide layer stacked on the substrate in sequence, a hydrogen content of the second silicon oxide layer is greater than 4%, a hydrogen content of the first silicon oxide layer is less than the hydrogen content of the second silicon oxide layer, the hydrogen content of the first silicon oxide layer is less than or equal to 4%, and a refractive index of the second silicon oxide layer is greater than a refractive index of the first silicon oxide layer.

Optionally, in some embodiments of the present disclosure, a thickness of the first silicon oxide layer is greater than or equal to 500 angstroms.

Optionally, in some embodiments of the present disclosure, a thickness of the second silicon oxide layer is greater than a thickness of the first silicon oxide layer.

Optionally, in some embodiments of the present disclosure, the buffer layer further includes a third silicon oxide layer stacked on a side of the second silicon oxide layer away from the substrate, and a hydrogen content of the third silicon oxide layer is less than the hydrogen content of the second silicon oxide layer.

Accordingly, an embodiment of the present disclosure further provides a display panel, and the display panel includes the driving substrate described in any of the above embodiments. For example, the driving substrate includes a transistor structure, and the transistor structure includes:
a substrate;
a buffer layer disposed on the substrate; and
a transistor disposed on a side of the buffer layer away from the substrate;
the buffer layer includes a first silicon oxide layer and a second silicon oxide layer stacked on the substrate in sequence, a hydrogen content of the second silicon oxide layer is greater than 4%, a hydrogen content of the first silicon oxide layer is less than the hydrogen content of the second silicon oxide layer, and the hydrogen content of the first silicon oxide layer is less than or equal to 4%;
the buffer layer further includes a third silicon oxide layer stacked on a side of the second silicon oxide layer away from the substrate, and a hydrogen content of the third silicon oxide layer is less than the hydrogen content of the second silicon oxide layer.

Optionally, in some embodiments of the present disclosure, the hydrogen content of the second silicon oxide layer is between 5% and 9%, and the hydrogen content of the third silicon oxide layer is greater than or equal to 2% and less than or equal to 4%.

Optionally, in some embodiments of the present disclosure, a thickness of the first silicon oxide layer is greater than or equal to 500 angstroms.

The buffer layer of the transistor structure in embodiments of the present disclosure uses the first silicon oxide layer as a bottom layer of the buffer layer, and the hydrogen content of the first silicon oxide layer is less than the hydrogen content of the second silicon oxide layer. That is, compared with the second silicon oxide layer, the first silicon oxide layer located at the bottom is an oxygen-rich film layer. Since the first silicon oxide layer contains less hydrogen, the first silicon oxide layer has fewer silicon-hydrogen bonds, which can further improve the stability of the fully silicon oxide buffer layer in early stages of film formation.

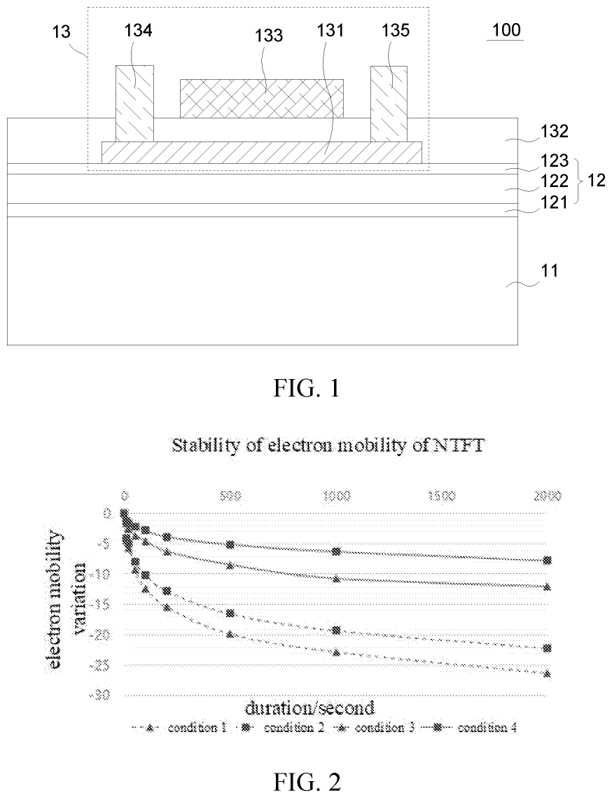

Referring to FIG. 1, an embodiment of the present disclosure provides a transistor structure 100, the transistor structure includes a substrate 11, a buffer layer 12 and a transistor 13.

The buffer layer 12 is disposed on the substrate 11. The transistor 13 is disposed on a side of the buffer layer 12 away from the substrate 11.

The buffer layer 12 includes a first silicon oxide layer 121 and a second silicon oxide layer 122 stacked on the substrate 11 in sequence. A hydrogen content of the second silicon oxide layer 122 is greater than 4%, and a hydrogen content of the first silicon oxide layer 121 is less than the hydrogen content of the second silicon oxide layer 122.

The buffer layer 12 of the transistor structure 100 in this embodiment of the present disclosure uses the first silicon oxide layer 121 as a bottom layer of the buffer layer, and the hydrogen content of the first silicon oxide layer 121 is less than the hydrogen content of the second silicon oxide layer 122. That is, compared with the second silicon oxide layer, the first silicon oxide layer 121 located at the bottom is an oxygen-rich film layer. Since the first silicon oxide layer 121 contains less hydrogen, the first silicon oxide layer 121 has fewer silicon-hydrogen bonds, which can further improve the stability of the fully silicon oxide buffer layer in early stages of film formation.

It should be understood that the hydrogen content refers to a percentage of the number of hydrogen atoms in the film layer to the total number of atoms in the film layer. For example, the hydrogen content of the first silicon oxide layer 121 refers to the percentage of the number of hydrogen atoms in the first silicon oxide layer 121 to the total number of atoms in the first silicon oxide layer 121.

Time Of Flight Secondary Ion Mass Spectrometry (TOF SIMS) can be used to analyze the content (number) of hydrogen atoms and the content (number) of other atoms in the film layer.

Secondly, in the process of preparing the silicon oxide layer, the plasma enhanced chemical vapor deposition (PECVD) process is used to prepare the silicon oxide layer. During the process, it is required that nitrous oxide (N₂O) and silane (SiH₄) are introduced into the chamber of the PECVD equipment to generate plasma and form SiOₓ:H (hydrogenated silicon oxide mixture) which is deposited on the substrate 11, so that the silicon oxide layer formed contains hydrogen element. The lower the hydrogen content is, the greater the amount of SiO positive ions is, which represent that the silicon oxide layer is richer in oxygen, otherwise, the silicon oxide layer is richer in silicon.

In addition, silicon-hydrogen bonds (Si—H) are also generated when the silicon oxide layer is formed. Silicon-hydrogen bonds are easily broken at high temperatures, leading to hydrogen evolution, thereby causing film instability.

Therefore, the richer in oxygen the first silicon oxide layer 121 located at the bottom is, the smaller the hydrogen content and the fewer silicon-hydrogen bonds will be, so that the quality stability of the film layer is getting higher, and thus the quality stability of the film layer of the entire buffer layer 12 is getting higher, which can improve the stability of the transistor 13.

Optionally, the hydrogen content of the first silicon oxide layer 121 is less than or equal to 4%, so as to ensure excellent stability in film formation of the first silicon oxide layer 121.

Optionally, the hydrogen content of the first silicon oxide layer 121 is greater than or equal to 2%. Due to the limitations of the PECVD process, currently, the minimum hydrogen content of the silicon oxide layer can reach 2%. Therefore, the hydrogen content of the first silicon oxide layer 121 is greater than or equal to 2%.

Therefore, the hydrogen content of the first silicon oxide layer 121 may be 2%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9% or 4%.

Optionally, the transistor 13 includes an active layer 131, a gate insulating layer 132, a gate 133, a source 134 and a drain 135. The active layer 131 is disposed on the side of the buffer layer 12 away from the substrate 11. The gate insulating layer 132 covers the active layer 131. The gate 133 is disposed on the side of the gate insulating layer 132 away from the substrate 11. The source 134 is connected to one end of the active layer 131. The drain 135 is connected to another end of the active layer 131. The material of the active layer 131 is monocrystalline silicon or polycrystalline silicon.

Optionally, the gate insulation layer 132 also covers the buffer layer 12. The gate 133, the source 134 and the drain 135 are disposed on the gate insulating layer 132 in a same layer.

In some embodiments, the gate 133 may also be disposed in different layers from the source 134 and the drain 135 respectively, and be separated by an insulating layer.

Optionally, the thickness of the first silicon oxide layer 121 is greater than or equal to 500 angstroms.

The thickness of the first silicon oxide layer 121 is set to be greater than or equal to 500 angstroms, so as to better improve the stability of the first silicon oxide layer 121 and try to ensure a stable base layer for subsequent silicon oxide layers, thereby improving the stability of the entire buffer layer 12.

Optionally, the thickness of the first silicon oxide layer 121 may be 500 angstroms, 550 angstroms, 600 angstroms, 650 angstroms, 700 angstroms, 750 angstroms, 800 angstroms, 850 angstroms, 900 angstroms, 950 angstroms, 1000 angstroms, 1050 angstroms, 1100 angstroms, 1150 angstroms, 1200 angstroms, 1250 angstroms, 1300 angstroms, 1350 angstroms, 1400 angstroms, 1450 angstroms or 1500 angstroms, and the like.

Optionally, the refractive index of the second silicon oxide layer 122 is greater than the refractive index of the first silicon oxide layer 121.

It can be understood that the higher the refractive index of the film layer is, the higher the efficiency of space filling of the film layer is. Therefore, compared with the first silicon oxide layer 121, the second silicon oxide layer 122 has a higher efficiency of space filling to block the penetration of alkaline cations, and thus reducing the risk of alkaline cations invading the channel of the transistor 13, and improving the stability of the transistor 13.

Optionally, the thickness of the second silicon oxide layer 122 is greater than the thickness of the first silicon oxide layer 121.

It can be understood that the greater the thickness of the second silicon oxide layer 122 is, the better its effect of blocking alkaline cations is. Therefore, the above arrangement can improve the performance of the second silicon oxide layer 122 in blocking alkaline cations.

Optionally, the hydrogen content of the second silicon oxide layer 122 is between 5% and 9%. That is, the second silicon oxide layer 122 is a silicon-rich film layer. The efficiency of space filling of the silicon-rich film layer is greater than the efficiency of space filling of the oxygen-rich film layer. The greater the hydrogen content is, the greater the efficiency of space filling of the film layer is, and the greater the refractive index is, and thus, it has a greater impact on optics. Therefore, the hydrogen content of the second silicon oxide layer 122 is set to be between 5% and 9%, which not only satisfies the performance of blocking alkaline cations, but also meets the optical requirements.

Optionally, the hydrogen content of the second silicon oxide layer 122 may be 5%, 5.5%, 6%, 6.5%, 7%, 7.5%, 8%, 8.5% or 9%.

Optionally, the refractive index of the second silicon oxide layer 122 is between 1.50 and 1.58, such as 1.50, 1.51, 1.52, 1.53, 1.54, 1.55, 1.56, 1.57 or 1.58.

The refractive index of the second silicon oxide layer 122 is selected to be between 1.50 and 1.58, which can meet the requirement of blocking alkaline cations, while meeting optical requirements.

Optionally, the buffer layer 12 also includes a third silicon oxide layer 123 stacked on the side of the second silicon oxide layer 122 away from the substrate 11. The hydrogen content of the third silicon oxide layer 123 is less than that of the second silicon oxide layer 122.

The third silicon oxide layer 123 with a lower hydrogen content than that of the second silicon oxide layer 122 is used to directly contact the active layer 131 of the transistor 13, so that the contact interface between the active layer 131 and the third silicon oxide layer 123 tends to be stable, thereby improving the stability of the transistor 13.

Optionally, the hydrogen content of the third silicon oxide layer 123 is greater than or equal to 2% and less than or equal to 4%.

It should be understood that the material of the active layer 131 of the transistor 13 is a silicon semiconductor, and there are suspended silicon ions in the active layer 131. The suspended silicon ions can bind with the hydrogen ions of the third silicon oxide layer 123 to form silicon-hydrogen bonds, which makes the interface between the third silicon oxide layer 123 and the active layer 131 more stable than unbound silicon and hydrogen in a suspended state.

Secondly, dehydrogenation annealing is performed during the process of preparing the active layer 131. The third silicon oxide layer 123 itself has silicon-hydrogen bonds, if the third silicon oxide layer 123 has an excessive hydrogen content, it will increase the difficulty of hydrogen removal. If there are too many broken silicon-hydrogen bonds, it will lead to unstable film quality of the third silicon oxide layer 123. Therefore, the hydrogen content of the third silicon oxide layer 123 should not be too high, and the hydrogen content of the third silicon oxide layer 123 is defined to be less than or equal to 4% in embodiments of the present disclosure.

After performing the dehydrogenation annealing, the active layer 131 and the third silicon oxide layer 123 then need to be supplemented with hydrogen, so that the interface between the active layer 131 and the third silicon oxide layer 123 forms silicon-hydrogen bonds to improve the stability of the interface. The amount of hydrogen removed and the amount of hydrogen supplemented are relatively balanced, that is, as much hydrogen is removed, as much hydrogen is supplemented. However, due to accuracy issues of the equipment, the amount of hydrogen removed and the amount of hydrogen supplemented cannot be balanced with 100%, so the amount of hydrogen removed and the amount of hydrogen supplemented are relatively balanced.

Therefore, the hydrogen content of the third silicon oxide layer 123 is greater than or equal to 2%, which is beneficial to improving the stability of the transistor 13.

Optionally, the hydrogen content of the third silicon oxide layer 123 may be 2%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9% or 4%.

Optionally, the thickness of the first silicon oxide layer 121 is between 500 angstroms and 1000 angstroms, the thickness of the second silicon oxide layer 122 is between 1000 angstroms and 2000 angstroms, the thickness of the third silicon oxide layer 123 is between 500 angstroms and 1000 angstroms, and the refractive index of the second silicon oxide layer 122 is greater than the refractive index of the third silicon oxide layer 123.

It should be noted that the refractive index of the buffer layer 12 depends on the refractive index and film layer of each of the first silicon oxide layer 121, the second silicon oxide layer 122 and the third silicon oxide layer 123.

In order to satisfy the need of the buffer layer 12 to block alkaline cations and the optical requirements, the difference in refractive index between the second silicon oxide layer 122 and the first silicon oxide layer 121, and that between the second silicon oxide layer 122 and the third silicon oxide layer 123 are maintained to be relatively small, respectively.

Since the refractive index of the second silicon oxide layer 122 is relatively high, a thicker second silicon oxide layer 122 is arranged to facilitate faster adaptation to the refractive index of the buffer layer 12 and to the need to block alkaline cations, and avoid the buffer layer 12 being too thick.

Optionally, the refractive index of the first silicon oxide layer 121 is between 1.45 and 1.49, and the refractive index of the third silicon oxide layer 123 is between 1.45 and 1.49.

Since the refractive index of the second silicon oxide layer 122 is between 1.50 and 1.58, the difference in refractive index between the first silicon oxide layer 121 and the second silicon oxide layer 122, and that between the third silicon oxide layer 123 and the second silicon oxide layer 122 are respectively between 0.01 to 0.13, so that the buffer layer 12 has a better optical quality.

In addition, the refractive index of the first silicon oxide layer 121 is between 1.45 and 1.49. The refractive index of the third silicon oxide layer 123 is between 1.45 and 1.49. The refractive index of the second silicon oxide layer 122 is between 1.50 and 1.58. The thickness of the first silicon oxide layer 121 is between 500 angstroms and 1000 angstroms, the thickness of the second silicon oxide layer 122 is between 1000 angstroms and 2000 angstroms, and the thickness of the third silicon oxide layer 123 is between 500 angstroms and 1000 angstroms.

By selecting the refractive index and film thickness of each film layer, the effects of blocking alkaline cations, having better optical quality, and thinning the buffer layer 12 can be better achieved.

Optionally, the refractive index of each of the first silicon oxide layer 121 and the third silicon oxide layer 123 may be 1.45, 1.46, 1.47, 1.48 or 1.49.

The thickness of each of the first silicon oxide layer 121 and the third silicon oxide layer 123 may be 500 angstroms, 550 angstroms, 600 angstroms, 650 angstroms, 700 angstroms, 750 angstroms, 800 angstroms, 850 angstroms, 900 angstroms, 950 angstroms or 1000 angstroms.

The thickness of the second silicon oxide layer 122 may be 1000 angstroms, 1050 angstroms, 1100 angstroms, 1150 angstroms, 1200 angstroms, 1250 angstroms, 1300 angstroms, 1350 angstroms, 1400 angstroms, 1450 angstroms, 1500 angstroms, 1550 angstroms, 1600 angstroms, 1650 angstroms, 1700 angstroms, 1750 angstroms, 1800 angstroms, 1850 angstroms, 1900 angstroms, 1950 angstroms or 2000 angstroms.

It should be noted that in the process of preparing the buffer layer 12, different ratios of nitrous oxide to silane (N₂O/SiH₄) can be used to form silicon oxide layers with different film thicknesses. The greater the ratio of nitrous oxide to silane is, the less the hydrogen content of the film layer is, that is, the film layer is rich in oxygen. Otherwise, the film layer is rich in silicon.

As shown in Table 1:

TABLE 1

| | Scheme 1 | | Scheme 2 | | Scheme 3 | |
|---|---|---|---|---|---|---|
| | film | N₂O/ | film | N₂O/ | film | N₂O/ |
| | thickness | SiH₄ | thickness | SiH₄ | thickness | SiH₄ |
| the third | 500 | 15 | 1000 | 15 | 500 | 26 |
| silicon oxide | angstroms | | angstroms | | angstroms | |
| layer | | | | | | |
| the second | 2000 | 6 | 1500 | 6 | 2000 | 6 |
| silicon oxide | angstroms | | angstroms | | angstroms | |
| layer | | | | | | |
| the first silicon | 500 | 15 | 500 | 15 | 500 | 26 |
| oxide layer | angstroms | | angstroms | | angstroms | |

Embodiments of the present disclosure are not limited to the schemes listed above, and the film thickness and gas ratio can be changed and combined according to requirements.

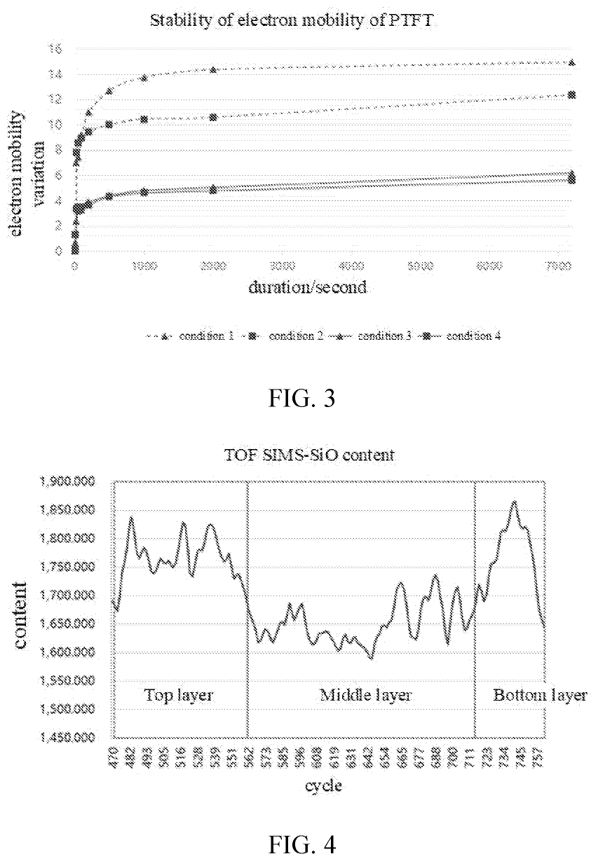

In addition, according to Table 2, FIG. 2 and FIG. 3, it can be seen that the electron mobility of the transistor 13 having a buffer layer adopting a stacked structure of the first silicon oxide layer 121+the second silicon oxide layer 122+the third silicon oxide layer 123 is more stable. The thicker the first silicon oxide layer 121 is, the better the stability is.

TABLE 2
Buffer layer

| | Condi- | Condi- | Condi- | Condi- |
|---|---|---|---|---|
| | tion 1 | tion 2 | tion 3 | tion 4 |
| Number of | One | One | Three (stacked | Three (stacked |
| film layers | | | structure in | structure in |
| | | | the present | the present |
| | | | disclosure) | disclosure) |
| Film | 3000 | 3000 | 500 angstroms/ | 1000 angstroms/ |
| thickness | angstroms | angstroms | 2000 angstroms/ | 1500 angstroms/ |
| | | | 500 angstroms | 500 angstroms |
| N₂O/SiH₄ | 6 | 9 | 15/6/15 | 15/6/15 |

Among them, the stability of electron mobility of the transistor corresponding to condition 4 is the best.

Secondly, Time Of Flight Secondary Ion Mass Spectrometry (TOF SIMS) can be used to analyze the buffer layer 12, and different film layers can be distinguished by analyzing the change trend of the contents of H or SiO, or the like.

For example, film layers of the sample-buffer layer 12 includes: the first silicon oxide layer (bottom layer)+the second silicon oxide layer (middle layer)+the third silicon oxide layer (top layer), and the corresponding film thickness is 500 angstroms/1500 angstroms/500 angstroms, respectively. By analyzing the SiO content (number) of the sample-buffer layer 12 by TOF SIMS, the top layer, the middle layer and the bottom layer can be distinguished, as shown in FIG. 4.

An embodiment of the present disclosure further provides a driving substrate, and the driving substrate includes the transistor structure 100 described in any of the above embodiments.

The transistor structure of the driving substrate in this embodiment is similar or identical to the transistor structure 100 described in any of the above embodiments, and will not be described again herein.

Optionally, the driving substrate may be an array substrate or a driving backplane. The array substrate can be used in liquid crystal display panels. The driving backplane can be used in organic light emitting diode display panels, inorganic light emitting diode display panels, micro light emitting diode display panels, sub-millimeter light emitting diode display panels, quantum dot light emitting diode display panels or electrophoretic display panels, and the like.

The buffer layer 12 of the transistor structure 100 in the driving substrate of the embodiments of the present disclosure uses the first silicon oxide layer 121 as the bottom layer of the buffer layer, and the hydrogen content of the second silicon oxide layer 122 is greater than 4%. The hydrogen content of the first silicon oxide layer 121 is less than the hydrogen content of the second silicon oxide layer 122. That is, compared with the second silicon oxide layer 122, the first silicon oxide layer 121 located at the bottom is an oxygen-rich film layer. Since the first silicon oxide layer 121 contains less hydrogen, the first silicon oxide layer 121 has fewer silicon-hydrogen bonds, which can improve the stability of the fully silicon oxide buffer layer 12 in early stages of film formation, thereby improving the stability of electron mobility in the thin film transistor.

An embodiment of the present disclosure further provides a display panel, and the display panel includes the driving substrate described in any of the above embodiments.

Optionally, the display panel may be a liquid crystal display panel, an organic light emitting diode display panel, an inorganic light emitting diode display panel, a micro light emitting diode display panel, a sub-millimeter light emitting diode display panel, a quantum dot light emitting diode display panel or an electrophoretic display panel.

The buffer layer 12 of the transistor structure 100 in the display panel of the embodiments of the present disclosure adopts the first silicon oxide layer 121 as the bottom layer of the buffer layer, in which the hydrogen content of the second silicon oxide layer 122 is greater than 4%. The hydrogen content of the first silicon oxide layer 121 is less than the hydrogen content of the second silicon oxide layer 122. That is to say, compared with the second silicon oxide layer, the first silicon oxide layer 121 located at the bottom is an oxygen-rich film layer. Since the first silicon oxide layer 121 contains less hydrogen, the first silicon oxide layer 121 also has fewer silicon-hydrogen bonds, which can improve the stability of the fully silicon oxide buffer layer in early stages of film formation, thereby improving stability of electron mobility in the thin film transistor.

The transistor structures, driving substrates and display panels provided by embodiments of the present disclosure are introduced in detail in the above, and specific examples are used herein to illustrate the principles and implementations of the present disclosure. The description of the above embodiments is only intended to help to understand methods and core ideas of the present disclosure. At the same time, for those skilled in the art, there will be changes in specific implementations and application scope based on the ideas of the present disclosure. In summary, the content of this description should not be understood as a limitation of the present disclosure.

What is claimed is:

1. A transistor structure comprising:
a substrate;
a buffer layer disposed on the substrate; and
a transistor disposed on a side of the buffer layer away from the substrate;
wherein the buffer layer comprises a first silicon oxide layer and a second silicon oxide layer stacked on the substrate in sequence, a hydrogen content of the second silicon oxide layer is greater than 4%, and a hydrogen content of the first silicon oxide layer is less than the hydrogen content of the second silicon oxide layer.

2. The transistor structure according to claim 1, wherein the hydrogen content of the first silicon oxide layer is less than or equal to 4%.

3. The transistor structure according to claim 1, wherein a thickness of the first silicon oxide layer is greater than or equal to 500 angstroms.

4. The transistor structure according to claim 1, wherein a refractive index of the second silicon oxide layer is greater than a refractive index of the first silicon oxide layer.

5. The transistor structure according to claim 4, wherein a thickness of the second silicon oxide layer is greater than a thickness of the first silicon oxide layer.

6. The transistor structure according to claim 5, wherein the hydrogen content of the second silicon oxide layer is between 5% and 9%.

7. The transistor structure according to claim 6, wherein the refractive index of the second silicon oxide layer is between 1.50 and 1.58.

8. The transistor structure according to claim 1, wherein the buffer layer further comprises a third silicon oxide layer stacked on a side of the second silicon oxide layer away from the substrate, and a hydrogen content of the third silicon oxide layer is less than the hydrogen content of the second silicon oxide layer.

9. The transistor structure according to claim 8, wherein the hydrogen content of the third silicon oxide layer is greater than or equal to 2% and less than or equal to 4%.

10. The transistor structure according to claim 9, wherein a thickness of the first silicon oxide layer is between 500 angstroms and 1000 angstroms, a thickness of the second silicon oxide layer is between 1000 angstroms and 2000 angstroms, a thickness of the third silicon oxide layer is between 500 angstroms and 1000 angstroms, and a refractive index of the second silicon oxide layer is greater than a refractive index of the third silicon oxide layer.

11. The transistor structure according to claim 10, wherein a refractive index of the first silicon oxide layer is between 1.45 and 1.49, and the refractive index of the third silicon oxide layer is between 1.45 and 1.49.

12. The transistor structure according to claim 1, wherein the hydrogen content of the first silicon oxide layer is greater than or equal to 2%.

13. The transistor structure according to claim 8, wherein the transistor comprises an active layer, a gate insulating layer, a gate, a source and a drain, the active layer is disposed on the side of the buffer layer away from the substrate, the gate insulating layer covers the active layer, the gate is disposed on a side of the gate insulating layer away from the substrate, the source is connected to one end of the active layer, the drain is connected to another end of the active layer, and a material of the active layer is monocrystalline silicon or polycrystalline silicon.

14. A driving substrate comprising a transistor structure, wherein the transistor structure comprises:
a substrate;
a buffer layer disposed on the substrate; and
a transistor disposed on a side of the buffer layer away from the substrate;
wherein the buffer layer comprises a first silicon oxide layer and a second silicon oxide layer stacked on the substrate in sequence, a hydrogen content of the second silicon oxide layer is greater than 4%, a hydrogen content of the first silicon oxide layer is less than the hydrogen content of the second silicon oxide layer, the hydrogen content of the first silicon oxide layer is less than or equal to 4%, and a refractive index of the second silicon oxide layer is greater than a refractive index of the first silicon oxide layer.

15. The driving substrate according to claim 14, wherein a thickness of the first silicon oxide layer is greater than or equal to 500 angstroms.

16. The driving substrate according to claim 14, wherein a thickness of the second silicon oxide layer is greater than a thickness of the first silicon oxide layer.

17. The driving substrate according to claim 14, wherein the buffer layer further comprises a third silicon oxide layer stacked on a side of the second silicon oxide layer away from the substrate, and a hydrogen content of the third silicon oxide layer is less than the hydrogen content of the second silicon oxide layer.

18. A display panel comprising a driving substrate, wherein the driving substrate comprises a transistor structure, and the transistor structure comprises:
a substrate;
a buffer layer disposed on the substrate; and
a transistor disposed on a side of the buffer layer away from the substrate;
wherein the buffer layer comprises a first silicon oxide layer and a second silicon oxide layer stacked on the substrate in sequence, a hydrogen content of the second silicon oxide layer is greater than 4%, a hydrogen content of the first silicon oxide layer is less than the hydrogen content of the second silicon oxide layer, and the hydrogen content of the first silicon oxide layer is less than or equal to 4%;
the buffer layer further comprises a third silicon oxide layer stacked on a side of the second silicon oxide layer away from the substrate, a hydrogen content of the third silicon oxide layer is less than the hydrogen content of the second silicon oxide layer.

19. The display panel according to claim 18, wherein the hydrogen content of the second silicon oxide layer is between 5% and 9%, and the hydrogen content of the third silicon oxide layer is greater than or equal to 2% and less than or equal to 4%.

20. The display panel according to claim 18, wherein a thickness of the first silicon oxide layer is greater than or equal to 500 angstroms.
